(19) United States
(12) Patent Application Publication
(10) Pub. No.: US 2023/0275186 A1
(43) Pub. Date: Aug. 31, 2023

(54) PATTERNED SUBSTRATE AND PREPARATION PROCESS THEREOF, AND LIGHT-EMITTING DIODE AND PREPARATION PROCESS THEREOF

(71) Applicant: FUJIAN JING'AN OPTOELECTRONICS CO., LTD., Quanzhou (CN)

(72) Inventors: Binbin LI, Quanzhou (CN); Yao HUO, Quanzhou (CN); Xianda SU, Quanzhou (CN); Juiping LI, Quanzhou (CN); Furen WU, Quanzhou (CN); Xinglin WANG, Quanzhou (CN); Xiaoyang MEI, Quanzhou (CN)

(21) Appl. No.: 18/315,212

(22) Filed: May 10, 2023

Related U.S. Application Data
(63) Continuation-in-part of application No. PCT/CN2020/139438, filed on Dec. 25, 2020.

(51) Int. Cl. H01L 33/22

(52) U.S. Cl. CPC H01L 33/22

(57) ABSTRACT

A patterned substrate includes a substrate body having a surface and a plurality of patterned structures periodically arranged on the surface of the substrate body, where each of the patterned structures includes a first portion formed on the surface of the substrate body, and a second portion formed on the first portion, and where any two adjacent ones of the patterned structures are spaced apart from one another by a minimum distance of not greater than 0.1 μm. A light-emitting diode includes the patterned substrate and a semiconductor epitaxial structure formed thereon. A process for preparing the patterned substrate and a process for preparing the light-emitting diode are also disclosed.

### CROSS-REFERENCE TO RELATED APPLICATION

This application is a continuation-in-part (CIP) application of PCT International Application No. PCT/CN2020/139438, filed on Dec. 25, 2020.

### FIELD

The disclosure relates to a semiconductor device, and more particularly, to a patterned substrate and a preparation process thereof, and a light-emitting diode (LED) and a preparation process thereof.

### BACKGROUND

In a conventional LED, due to lattice mismatch and coefficient of thermal expansion mismatch between a heterogeneous substrate and an epitaxial layer grown thereon, the interior of the epitaxial layer has a high dislocation density which may lead to charge carrier leakage, thereby reducing internal quantum efficiency.

Substrate patterning has been developed in order to suppress dislocation glide and internal dislocation of the epitaxial layer, thereby obtaining an epitaxial layer with low dislocation density and high crystal quality. The substrate patterning is carried out by forming a pattern with a plurality of microstructures on a heterogeneous substrate so as to form a patterned substrate. The epitaxial layer is formed by epitaxially growing an LED material on a surface of the patterned substrate. The microstructures formed on the surface of the patterned substrate can promote growth of the epitaxial layer so as to prevent defects of dislocation from propagating toward a surface of the epitaxial layer that is away from the patterned substrate, to thereby improve the internal quantum efficiency of the LED thus fabricated. Generally speaking, the less of the surface of the patterned substrate that is used for growing the epitaxial layer (i.e., the smaller an epitaxial region), the lower the dislocation density in the epitaxial layer formed thereon, and the higher the brightness of the LED. However, the amount of reduction of the epitaxial region as a proportion of the surface of the patterned substrate that is achievable with current technology is limited. In addition, by making the epitaxial region too small, difficulties may be encountered during the formation of the epitaxial layer which may be adverse to the formation of a high-quality epitaxial layer.

### SUMMARY

Therefore, an object of the disclosure is to provide a patterned substrate and a preparation process thereof and a light-emitting diode and a preparation process thereof that can alleviate at least one of the drawbacks of the prior art.

According to the first aspect of the disclosure, the patterned substrate includes a substrate body having a surface, and a plurality of patterned structures periodically arranged on the surface of the substrate body. Each of the patterned structures includes a first portion formed on the surface of the substrate body, and a second portion formed on the first portion. Any two adjacent ones of the patterned structures are spaced apart from one another by a minimum distance of not greater than 0.1 μm.

According to the second aspect of the disclosure, the process for preparing the patterned substrate includes: (A) providing a substrate body having a surface; and (B) forming a plurality of patterned structures periodically arranged on the surface of the substrate body. Each of the patterned structures includes a first portion formed on the surface of the substrate body, and a second portion formed on the first portion. Any two adjacent ones of the patterned structures are spaced apart from one another by a minimum distance of not greater than 0.1 μm.

According to the third aspect of the disclosure, the light-emitting diode includes the patterned substrate of the present disclosure; and a semiconductor epitaxial structure formed on the surface of the substrate body of the patterned substrate that has the patterned structures.

According to the forth aspect of the disclosure, the process for preparing the light-emitting diode includes: (A) preparing a patterned substrate by the process for preparing the patterned substrate according to the present disclosure, and (B) forming a semiconductor epitaxial structure on a surface of the patterned substrate that has the patterned structures.

### BRIEF DESCRIPTION OF THE DRAWINGS

Other features and advantages of the disclosure will become apparent in the following detailed description of the embodiments with reference to the accompanying drawings. It is noted that various features may not be drawn to scale.

FIG. 1 is a top schematic view illustrating an embodiment of a patterned substrate according to the disclosure;

FIG. 2 is a schematic view of the patterned substrate according to the disclosure, illustrating an epitaxial region of the patterned substrate;

FIG. 3 is an Atomic Force Microscopy (AFM) image of the embodiment of the patterned substrate according to the disclosure;

FIGS. 4A and 4B are Scanning Electron Microscope (SEM) images of the embodiment of the patterned substrate according to the disclosure;

FIGS. 5A to 5F are cross-sectional schematic views illustrating consecutive steps of an embodiment of a process for preparing the patterned substrate according to the disclosure;

FIG. 6 is a schematic view illustrating an embodiment of a light-emitting diode structure according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

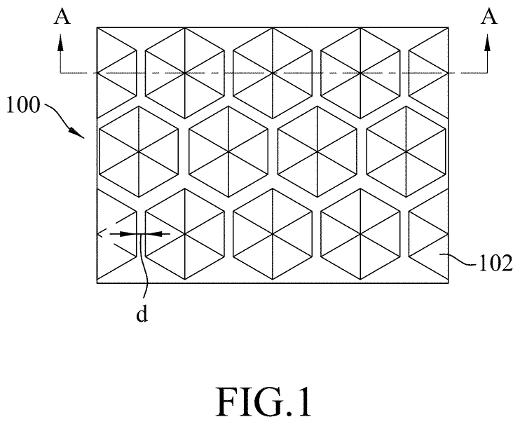

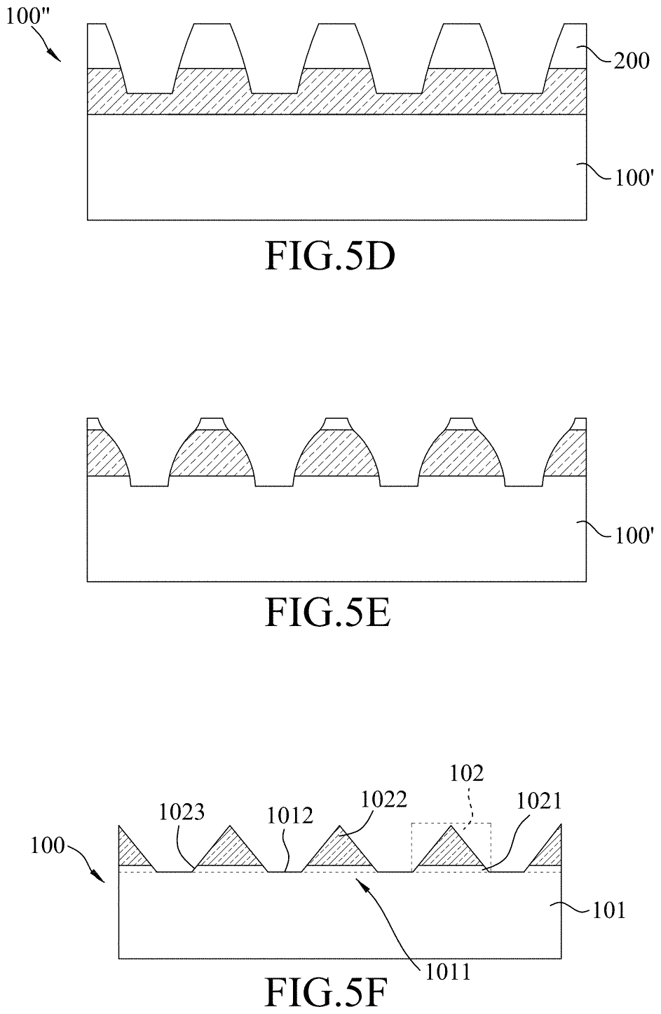

Referring to FIGS. 1 and 5F, an embodiment of a patterned substrate 100 of the present disclosure is shown. FIG. 5F is a cross-sectional schematic view of the patterned substrate 100 of FIG. 1 taken along line A-A. The patterned substrate 100 includes a substrate body 101 having a surface 1011, and a plurality of patterned structures 102 periodically arranged on the surface 1011 of the substrate body 101. Each of the patterned structures 102 includes a first portion 1021 formed on the surface 1011 of the substrate body 101, and a second portion 1022 formed on the first portion 1021. Any two adjacent ones of the patterned structures 102 are spaced apart from one another by a minimum distance (d) that is not greater than 0.1 μm. The patterned substrate 100 further includes an epitaxial region 103 that includes a portion 1012 of the surface 1011 of the substrate body 101 exposed from the patterned structures 102 and a portion 1023 of the first portion 1021 uncovered by the second portion 1022. Since the epitaxial region 103 is relatively small as proportion of the patterned substrate 100, growth of a semiconductor epitaxial layer (not shown) on the patterned substrate 100 may be improved, and a dislocation density in the semiconductor epitaxial structure thus formed may be advantageously reduced. Therefore, LEDs including the patterned substrate 100 may advantageously have increased brightness.

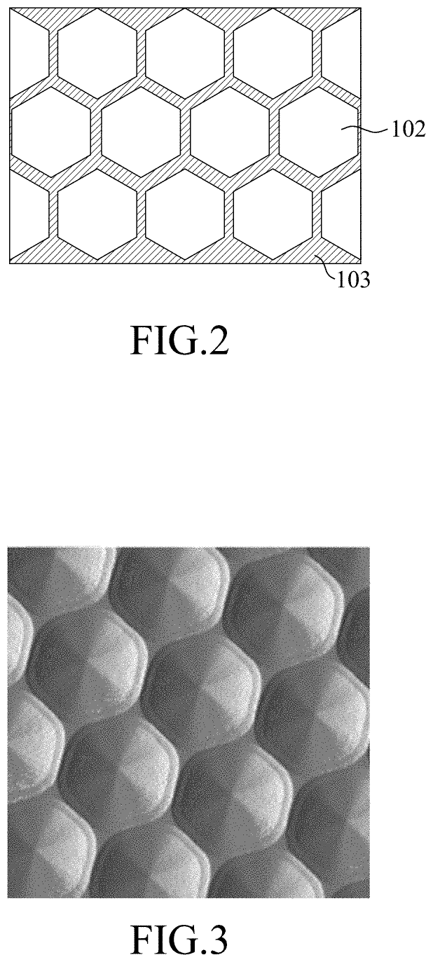

Specifically, the epitaxial region 1012 has an area less than 14% of a total area of the surface 1011 of the substrate body 101. Referring to FIG. 2, a schematic view of the epitaxial region 103 in relation to the substrate body 101 is shown. In certain embodiments, each of the patterned structure 102 has a first height, the first portion 1021 of the patterned structure 102 has a second height that is more than 0% and less than 100% of the second height.

In this embodiment, the first portion 1021 formed on the surface 1011 of the substrate body 101 is a truncated polygonal pyramid in shape (and therefore also referred to as the truncated polygonal pyramid 1021 hereafter), and the second portion 1022 formed on the truncated polygonal pyramid of the first portion 1021 is a polygonal pyramid in shape (and therefore also referred to as the polygonal pyramid 1022 hereafter). In certain embodiments, the first portion 1021 and the second portion 1022 of each of the patterned structures 102 has a top cross-sectional area and a bottom cross-sectional area, respectively, and the bottom cross-sectional area is adjacent to and the same as the top cross-sectional area. In certain embodiments, the second portion 1022 has cross-sectional areas that gradually decrease from-bottom-to-top. In certain embodiments, the second portion 1022 is a polygonal pyramid or a truncated polygonal pyramid in shape. In certain embodiments, for each of the patterned structures 102, the second height of the truncated polygonal pyramid 1021 is more than 0% and less than 100% of the first height of the patterned structure 102. In some embodiments, for each of the patterned structures 102, the second height of the truncated polygonal pyramid 1021 is more than 0% and less than 30% of the first height of the patterned structure 102. In certain embodiments, each of the polygonal pyramid-shaped second portions 1022, which is defined by a top, a polygonal base, a plurality of lateral faces extending between the top and the polygonal base and interconnected with each other respectively along a plurality of lateral edges extending between the top and the polygonal base, has an angle between each of the lateral edges and the polygonal base that ranges from 30° to 90°; for example, the angle may be, but is not limited to, ranging from 40° to 60°. Each of the first portion 1021, which is defined by a top, a polygonal base, a plurality of lateral faces extending between the top and the polygonal base and interconnected with each other respectively along a plurality of lateral edges extending between the top and the polygonal base, has an angle between each of the lateral edge and the polygonal base that ranges from 30° to 90°. In certain embodiments, the angle ranges, for example, may be, including but not limited to, ranging from 40° to 60°.

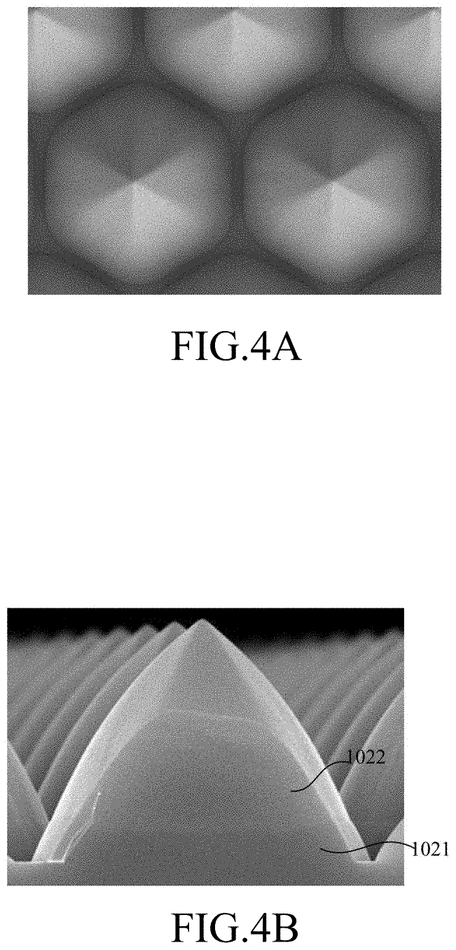

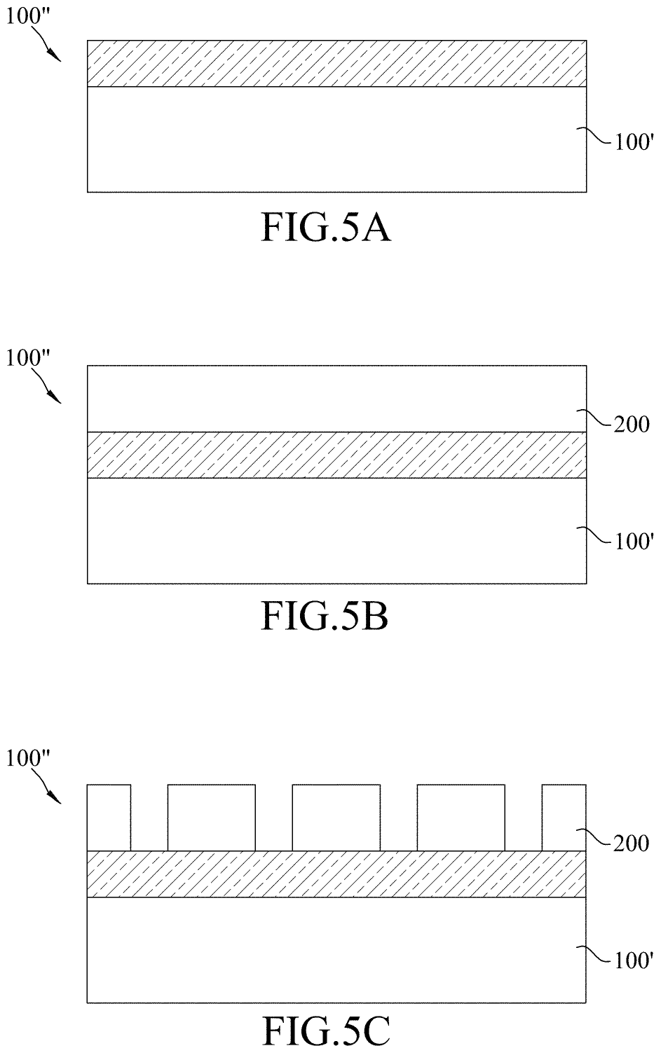

Referring to FIG. 3 and FIGS. 4A and 4B, AFM and SEM images of a patterned substrate according to an embodiment of the present disclosure are shown. Each of the truncated polygonal pyramid 1021 and the polygonal pyramid (or truncated polygonal pyramid) 1022 has of the lateral faces that are connected to one other and is angled to the polygonal base. The lateral faces may scatter the incident light, and therefore, may increase light scattering. In certain embodiments, the first portion 1021 is a truncated hexagonal pyramid in shape, and the second portion 1022 is a hexagonal pyramid or truncated hexagonal pyramid in shape. It should be noted that the polygonal base of the truncated polygonal pyramid and the polygonal pyramid in this embodiment may include, but are not limited to a polygon with sharp or rounded corners.

In this embodiment, the first portion 1021 includes a material that is the same as that of the substrate body 101. The second portion 1022 includes a material that is different from that of the first portion 1021. In certain embodiments, the second portion 1022 includes a nucleation-inhibiting material. The nucleation-inhibiting material is at least one transparent and non-light-absorbing material selected from the group consisting of SiO₂, SiN, Si₂N, Si₂N₃, Si₃N₄, MgF₂, CaF₂, Al₂O₃, SiO, TiO₂, Ti₃O₅, Ti₂O₃, TiO, Ta₂O₅, HfO₂, ZrO₂, Nb₂O₅, MgO, ZnO, Y₂O₃, CeO₂, CeF₃, LaF₃, YF₃, BaF₂, AlF₃, Na₃AlF₆, Na₅Al₃F₁₄, ZnS, ZnSe, and combinations thereof. The nucleation-inhibiting material is capable of inhibiting formation of a crystal nucleus. Since the nucleation-inhibiting materials are transparent and non-light-absorbing materials, in addition to reducing the dislocations formed in the semiconductor epitaxial structure subsequently grown thereon, the second portion 1022 can also reduce light absorption, so as to improve the light-emission efficiency for a light-emitting element including the patterned substrate 100 according to the present disclosure. The first portion 1021 includes at least one material selected from the group consisting of Al₂O₃, Si, SiC, PET, MgAl₂O₄, LiAlO₂, LiGaO₂, GaN, AlN, GaAs, Ga₂O₃, ZrB₂, ZnO, and combinations thereof.

In particular, the material of the first portion 1021, which is the same as the substrate body 101 in certain embodiments, has a relatively high refractive index, whereas the material of the second portion 1022, i.e., the nucleation-inhibiting material in this embodiment, has a relatively low refractive index. In other words, the refractive index of the second portion 1022 of the patterned structures 102, which is relatively far away from the substrate body 101, is lower than that of the first portion 1021, which is relatively close to the substrate body 101. With such an arrangement included in the patterned substrate, the LEDs may advantageously increase light reflection and thus light-emission efficiency. On the other hand, the polygonal pyramid 1022 includes a heterogeneous material that is not conducive to nucleation, and therefore, epitaxial growth may selectively go along surfaces other than the polygonal pyramids 1022. Epitaxial growth on and along the angled lateral faces of the truncated polygonal pyramid 1021 produces lateral or tilted dislocations. The lateral or tilted dislocations from two adjacent patterned structures 102 that may be offset from each other. In addition, threading dislocations may bend at interfaces into the lateral or tilted dislocations, and then terminate at the lateral faces of the patterned structures 102 or converge toward the tops of the patterned structures 102, thereby reducing the number of dislocations. Therefore, the patterned substrate 100 according to the present disclosure may reduce the dislocation density in the semiconductor epitaxial layer subsequently formed thereon, and avoid the development of epitaxial defect morphology commonly seen in the conventional art caused by the smaller spacing in the pattern which is unfavorable for epitaxy. By avoiding the development of epitaxial defect morphology, the patterned substrate 100 according to the present disclosure has improved epitaxy quality in the semiconductor epitaxial structure, and a reduction in ineffective charge recombinations, thereby improving the internal quantum efficiency for LEDs.

In summary, the patterned substrate 100 according to the present disclosure includes a substrate body 101, and patterned structures 102 periodically arranged on the surface 1011 of the substrate body 101. Since the region of the substrate body 101 that is exposed from the patterned structures 102 for epitaxially growing the semiconductor epitaxial structure is relatively small, the dislocation density in the semiconductor epitaxial structure formed subsequently by epitaxy may be reduced. In addition, by means of including the truncated polygonal pyramid 1021 and the polygonal pyramid (or truncated polygonal pyramid) 1022 in each patterned structure 102, the light scattering efficiency may be increased, and the light extraction efficiency may be improved. Further, due to the truncated polygonal pyramid 1021 having a relatively high refractive index and the polygonal pyramids 1022 having a relatively low refractive index and the nucleation inhibiting characteristics, the semiconductor epitaxial structure can be selectively grown on the patterned structures 102 with a reduced dislocation density and therefore an improved epitaxial quality.

FIGS. 5A-5F illustrate cross-sectional schematic views of consecutive steps of an embodiment of a process for preparing the patterned substrate 100 of FIG. 1 according to the present disclosure. The process includes: forming the patterned structures 102 on the surface 1011 of the substrate body 101. The patterned structures 102 are periodically arranged on the surface 1011 of the substrate body 101. Each of the patterned structures 102 includes the first portion 1021 formed on the surface 1011 of the substrate body 101, and the second portion 1022 formed on the first portion 1021. Any two adjacent ones of the patterned structures 102 are spaced apart from one another by a minimum distance of not greater than 0.1 μm, as described above for the patterned substrate 100.

Specifically, in this embodiment, forming the patterned structures 102 on the surface 1011 of the substrate body 101 includes steps S101 and S102. Step S101 includes providing a substrate 100′, and providing a nucleation-inhibiting material layer on the substrate 100′ so as to form a composite substrate 100″ as shown in FIG. 5A. In certain embodiments, the substrate 100′ may include at least one first material selected from the group consisting of Al₂O₃, Si, SiC, PET, MgAl₂O₄, LiAlO₂, LiGaO₂, GaN, AlN, GaAs, Ga₂O₃, ZrB₂, ZnO, and combinations thereof. The nucleation-inhibiting material layer may include a nucleation-inhibiting material, i.e. a second material that is different from the first material, and is formed on the substrate 100′ by a chemical vapor deposition process. In certain embodiments, the chemical vapor deposition is a plasma enhanced chemical vapor deposition (PECVD). The nucleation-inhibiting material can prevent the semiconductor epitaxial structure from nucleating thereon which improves the epitaxial quality of the semiconductor epitaxial structure. In certain embodiments, the nucleation-inhibiting material may have a low refractivity and thus may increase reflection of light. In certain embodiments, the nucleation-inhibiting material is transparent and non-light-absorbing. In certain embodiments, the nucleation-inhibiting material layer may include at least one material selected from SiO₂, SiN, Si₂N, Si₂N₃, Si₃N₄, MgF₂, CaF₂, Al₂O₃, SiO, TiO₂, Ti₃O₅, Ti₂O₃, TiO, Ta₂O₅, HfO₂, ZrO₂, Nb₂O₅, MgO, ZnO, Y₂O₃, CeO₂, CeF₃, LaF₃, YF₃, BaF₂, AlF₃, Na₃AlF₆, Na₅Al₃F₁₄, ZnS, ZnSe, and combinations thereof. In certain embodiments, the nucleation-inhibiting material layer has a thickness ranging from 0.1 μm to 20 μm. In certain embodiments, the thickness of the nucleation-inhibiting material layer ranges from 1.5 μm to 3 μm.

Step S102 includes forming the substrate body 101 and the plurality of patterned structures 102 from the composite substrate 100″ of FIG. 5A. Specifically, a photoresist mask layer 200 is deposited on the nucleation-inhibiting material layer of the composite substrate 100″ as shown in FIG. 5B. Then, the photoresist mask layer 200 is subjected to patterning by photolithography and dry etching, to remove portions of the photoresist mask layer 200 and expose portions of the composite substrate 100″. The patterned photoresist mask layer 200 on the composite substrate 100″ may have a pattern with densely and periodically arranged protrusions with a prism shape, as shown in FIG. 5C.

Subsequently, the composite substrate 100″, with the patterned photoresist mask layer 200 of FIG. 5C as a mask, is subjected to a further dry etching process. The dry etching process is proceeded until the patterned photoresist mask 200 is completely removed and then the substrate body 101 and the plurality of patterned structures 102 are formed. Referring to FIGS. 5D-5F, variations of the patterned photoresist mask 200 and the composite substrate 100″ during the dry etching process are illustrated. In this embodiment, the patterned structures 102 are periodically arranged, and each includes the truncated polygonal pyramid 1021 on the substrate body 101 and the polygonal pyramid 1022 on the truncated polygonal pyramid 1021. Any two adjacent ones of the patterned structures 102 are spaced apart from one another by a minimum distance of not greater than 0.1 μm (as shown in FIG. 1). An epitaxial region 103 is further formed. The epitaxial region 103 includes the portion 1012 of the surface 1011 of the substrate body 101 exposed from the patterned structures 102 and the portion 1023 of the first portion 1021 uncovered by the second portion 1022 of the patterned structure 102. The area of the epitaxial region 103 is less than 14% of the total area of the surface 1011 of the substrate body 101. Each of the patterned structures 102 has a height that is less than the total thickness of the composite substrate 100″ and is greater than the thickness of the nucleation-inhibiting material layer. In other words, the patterned structures 102 includes the entire unremoved nucleation-inhibiting material layer and part of the substrate 100′. In certain embodiments, the part of the substrate 100′ of each patterned structures 102 (corresponding to the first portion 1021) has a height ranging from 0.1 μm to 20 μm. In certain embodiments, the height of the part of the substrate 100′ is 1 μm to 3 μm; however, this is not a limitation of the disclosure. In this embodiment, the dry etching process is conducted with an etching gas such as CHF₃, CF₄, BCl₃, Ar, N₂, Cl₂, C₂F₆, etc. and with the following parameters: an output power of 1 to 2500 W for an upper electrode; an output power of 1-1500 W for a lower electrode, the flow rate of the etching gas at 1 to 200 sccm, and an etching time of 1-4000 s.

Specifically, by controlling ion bombardment directions and using the above parameters for the dry etching process, the patterned photoresist mask layer 200 and the composite substrate 100″ (as shown in FIG. 5C) are both etched downward and laterally at the same time. During the etching process, the patterned photoresist mask layer 200 is gradually removed (as shown in FIGS. 5D and 5E) while acting as a mask. That is, the height and the bottom cross-sectional area of the patterned photoresist mask layer 200 are both gradually reduced, and the bottom cross-sectional area of the patterned photoresist mask layer 200 is larger than the top cross-sectional area of the patterned photoresist mask layer 200 during the dry etching process. With different etch rates between the patterned photoresist mask layer 200 and the composite substrate 100″, the composite substrate 100″ is continuously removed as the material of the patterned photoresist mask layer 200 is gradually removed. After the patterned photoresist mask layer 200 is completely removed, downward and lateral etching into the composite substrate 100″ is still continued until patterned structures of a predetermined height (as shown in FIG. 5F) are formed. During the dry etching process, since the composite substrate 100″ is etched downward and laterally at the same time with the gradually reduced photoresist mask layer 200 as the mask, the patterned structures are formed as a top-narrow-and-bottom-wide patterned structure, such as a polygonal pyramid, a truncated polygonal pyramid in shape, or the like. In this embodiment, the second portion 1022 of the patterned structure is a polygonal pyramid. It should be noted that the etch rate of the nucleation-inhibiting material layer is similar to that of the substrate 100′.

After the dry etching process, the obtained structure is refined to have the patterned structures 102 with the top being the polygonal pyramid (or the truncated polygonal pyramid) 1022, and the cross-sectional area of the top of the truncated polygonal pyramid 1021 being equal to and close to that of the bottom of the polygonal pyramid 1022, as shown in FIG. 5F. The aforesaid refinement treatment may be conducted by laterally etching the obtained structure with different etching power conditions so as to modify the morphology of the patterned structures 102.

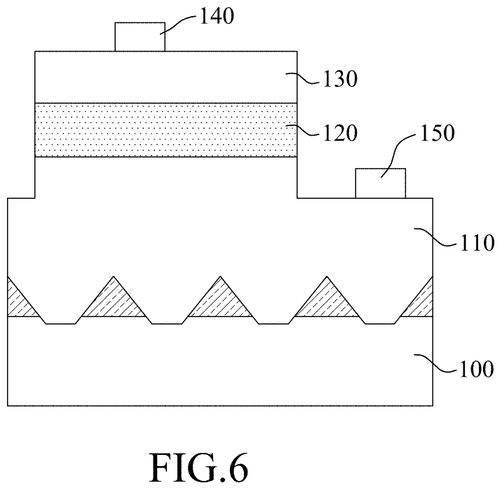

Referring to FIG. 6, an embodiment of a light-emitting diode (LED) according to the present disclosure is shown. The LED includes the patterned substrate 100 of the present disclosure, and a semiconductor epitaxial structure formed on a side of the patterned substrate 100 that has the patterned structures 102. The patterned substrate 100 includes the following epitaxial growth surfaces: the epitaxial region 103 including the exposed portion 1012 of the surface 1011 of the substrate body 101 and the uncovered portion 1012 of the polygonal pyramids 1021 and the lateral faces of the polygonal pyramid (or truncated polygonal pyramid in the other embodiments) 1022. The semiconductor epitaxial structure is formed on the epitaxial growth surfaces of the patterned substrate 100.

Specifically, the semiconductor epitaxial structure includes a first semiconductor layer 110, an active layer 120, and a second semiconductor layer 130 arranged in such order on the surfaces of the patterned substrate 100. The second semiconductor layer 130 includes a semiconductor material of a different PN type from that of the first semiconductor layer 110. In certain embodiments, the LED further includes a first electrode 140 formed on the second semiconductor layer 130, and a second electrode 150 formed on the first semiconductor layer 110. In certain embodiments, the LED further includes a transparent conductive layer formed on the first semiconductor layer 110 and the second semiconductor layer 130. The transparent conductive layer includes, for example but not limited to, ITO. The first electrode 140 and the second electrode 150 are both formed on the transparent conductive layer. In certain embodiments, the first semiconductor layer 110 is an N-type gallium nitride layer, and the second semiconductor layer 130 is a P-type gallium nitride layer. In certain embodiments, the substrate body 101 of the patterned substrate 100 and the truncated polygonal pyramid 1021 formed thereon include a sapphire material, while the polygonal pyramid 1022 includes a different material that is not conducive to nucleation, and is transparent and non-light absorbing. For example, the material of the polygonal pyramid 1022 includes at least one selected from the group consisting of SiO₂, SiN, Si₂N, Si₂N₃, Si₃N₄, MgF₂, CaF₂, Al₂O₃, SiO, TiO₂, Ti₃O₅, Ti₂O₃, TiO, Ta₂O₅, HfO₂, ZrO₂, Nb₂O₅, MgO, ZnO, Y₂O₃, CeO₂, CeF₃, LaF₃, YF₃, BaF₂, AlF₃, Na₃AlF₆, Na₅Al₃F₁₄, ZnS, ZnSe, and combinations thereof.

The present disclosure also provides a process for preparing the LED, including: preparing the patterned substrate 100 by the process according to the present disclosure; forming a semiconductor epitaxial structure on a side of the patterned substrate 100 that has the patterned structures 102; and forming electrodes on the epitaxial layer. The process for preparing the patterned substrate is as described above and not repeated here.

The step of forming the semiconductor epitaxial structure further includes: forming the first semiconductor layer 110, the active layer 120, and the second semiconductor layer 130 arranged in such order on the patterned substrate 100 by chemical vapor deposition. The second semiconductor layer 130 includes a semiconductor material of a different PN type from that of the first semiconductor layer 110. For example, the first semiconductor layer 110 may be an N-type gallium nitride layer, and the second semiconductor layer 130 may be a P-type gallium nitride layer. In certain embodiments, the substrate body 101 of the patterned substrate 100 and the truncated polygonal pyramid formed thereon are made of sapphire. The polygonal pyramid 1022 is made of a material that is not conducive to nucleation, and is transparent and non-light absorbing. For example, the material of the polygonal pyramid includes at least one selected from the group consisting of SiO₂, SiN, Si₂N, Si₂N₃, Si₃N₄, MgF₂, CaF₂, Al₂O₃, SiO, TiO₂, Ti₃O₅, Ti₂O₃, TiO, Ta₂O₅, HfO₂, ZrO₂, Nb₂O₅, MgO, ZnO, Y₂O₃, CeO₂, CeF₃, LaF₃, YF₃, BaF₂, AlF₃, Na₃AlF₆, Na₅Al₃F₁₄, ZnS, ZnSe, and combinations thereof. The step of forming the electrodes includes: forming a first electrode 140 on the second semiconductor layer 130, and forming a second electrode 150 on the first semiconductor layer 110. The first electrode 140 and the second electrode 150 may be made of one material including Al, Ni, Ti, Pt, Cr, Au, etc., or an alloy of at least two thereof.

In this embodiment, the LED includes the patterned substrate 100 of the present disclosure. Therefore, the LED according to the present disclosure has an epitaxial layer with an improved quality, thereby greatly improving the light extraction efficiency of the light-emitting diode, and significantly increasing the brightness.

In summary, the patterned substrate, the light-emitting diode and the processes for preparing the same as described in the present disclosure have at least the following arrangements and advantages: the patterned substrate 100 of the present disclosure includes the substrate body 101, and the patterned structures 102 formed and periodically arranged on the surface of the substrate body 101. Each of the patterned structures 102 includes the first portion formed on the surface of the substrate body 101, and the second portion formed over the first portion. Any two adjacent ones of the patterned structures 102 are spaced apart from one another by a minimum distance of not greater than 0.1 μm. Such structures include angled surfaces that may increase light scattering, and may improve the light extraction efficiency. Further, since the epitaxial region of the patterned substrate 100 that may be available for epitaxy is relatively small, the density of dislocations caused during the epitaxial process may be reduced to some extent. Furthermore, the patterned structures 102 includes the truncated polygonal pyramid 1021 with a higher refractive index and the polygonal pyramid 1022 with a lower refractive index. Since the difference between the refractive index of the truncated polygonal pyramid 1021 and that of the polygonal pyramid 1022 is significant, the reflection efficiency of light and the light extraction efficiency may increase. Also, the material of the polygonal pyramid 1022 is not conducive to nucleation, so the dislocation density in the epitaxial layer may be reduced, thereby increasing the brightness of the LED. In addition, lateral dislocations formed from epitaxial growth along one patterned structure 102 may be offset by those along an adjacent one, thereby reducing dislocations and improving the epitaxial quality of the epitaxial layer. Since the LED of the disclosure includes the patterned substrate 100 according to the disclosure, the brightness of the light-emitting diode is greatly improved.

The patterned substrate and the LED described in the disclosure enable effective reduction of the epitaxial region exposed from the patterned structures, thereby reducing the dislocation density and improving the light-emission efficiency. Also, the patterned structures 102 of the patterned substrate 100 have the lateral faces, so that the efficiency of light scattering and the light extraction efficiency/emission efficiency may be increased, thereby improving the brightness of the LED.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A patterned substrate, comprising:
a substrate body having a surface; and
a plurality of patterned structures periodically arranged on said surface of said substrate body, wherein each of said patterned structures includes a first portion formed on said surface of said substrate body, and a second portion formed on said first portion, and wherein any two adjacent ones of said patterned structures are spaced apart from one another by a minimum distance of not greater than 0.1 μm.

2. The patterned substrate of claim 1, wherein said first portion of one of said patterned structures has a top cross-sectional area, said second portion of the one of said patterned structures having a bottom cross-sectional area that is the same as the top cross-sectional area of said first portion.

3. The patterned substrate of claim 1, wherein said first portion is a truncated polygonal pyramid in shape, and said second portion has cross-sectional areas that are gradually decreasing from-bottom-to-top.

4. The patterned substrate of claim 3, wherein each of said second portions is a polygonal pyramid or a truncated polygonal pyramid in shape.

5. The patterned substrate of claim 4, wherein each of said second portions is in the polygonal pyramid shape, said polygonal pyramid having a top, a polygonal base, and a plurality of lateral edges extending between said top and said polygonal base, an angle between each of said lateral edges and said polygonal base ranging from 30° to 90°, and wherein the truncated polygonal pyramid of each of said first portions has a polygonal top face, a polygonal base, and a plurality of lateral edges extending between said polygonal top face and said polygonal base, an angle between each of said lateral edges and said polygonal base ranging from 30° to 90°.

6. The patterned substrate of claim 1, wherein each of said patterned structures has a first height, said first portion of said patterned structure having a second height that is more than 0% and less than 100% of the second height.

7. The patterned substrate of claim 1, wherein said first portion includes a material that is different from that of said second portion and that is the same as that of said substrate body.

8. The patterned substrate of claim 7, wherein said second portion is made of a nucleation-inhibiting material.

9. The patterned substrate of claim 8, wherein said nucleation-inhibiting material is at least one transparent and non-light absorbing material selected from the group consisting of SiO₂, SiN, Si₂N, Si₂N₃, Si₃N₄, MgF₂, CaF₂, Al₂O₃, SiO, TiO₂, Ti₃O₅, Ti₂O₃, TiO, Ta₂O₅, HfO₂, ZrO₂, Nb₂O₅, MgO, ZnO, Y₂O₃, CeO₂, CeF₃, LaF₃, YF₃, BaF₂, AlF₃, Na₃AlF₆, Na₅Al₃F₁₄, ZnS, ZnSe, and combinations thereof.

10. The patterned substrate of claim 1, further comprising an epitaxial region which includes a portion of said surface of said substrate body exposed from said patterned structures and a portion of said first portion uncovered by said second portion, said epitaxial region having an area less than 14% of a total area of said surface of said substrate body.

11. A process for preparing a patterned substrate, comprising:
(A) providing a substrate body having a surface; and
(B) forming a plurality of patterned structures periodically arranged on the surface of the substrate body, wherein each of the patterned structures includes a first portion formed on the substrate body, and a second portion formed on the first portion, and wherein any two adjacent ones of the patterned structures are spaced apart from one another by a minimum distance of not greater than 0.1 μm.

12. The process of claim 11, wherein the substrate body includes a first material, and wherein the step (B) of forming the plurality of patterned structures further comprises:
providing a substrate of a first material that has a substrate body and a first portion forming layer;
forming a layer of a second material that is different from the first material of the substrate;
forming a masking layer above the layer of the second material; and
removing a portion of the layer of the second material and a portion of the first portion forming layer by etching with the masking layer as a mask, so as to form the second portion with a remaining portion of the layer of the second material, and form the first portion with a remaining portion of the first portion forming layer.

13. The process of claim 12, wherein the second material is a nucleation-inhibiting material.

14. The process of claim 13, wherein the nucleation-inhibiting material is at least one transparent and non-light absorbing material selected from the group consisting of SiO₂, SiN, Si₂N, Si₂N₃, Si₃N₄, MgF₂, CaF₂, Al₂O₃, SiO, TiO₂, Ti₃O₅, Ti₂O₃, TiO, Ta₂O₅, HfO₂, ZrO₂, Nb₂O₅, MgO, ZnO, Y₂O₃, CeO₂, CeF₃, LaF₃, YF₃, BaF₂, AlF₃, Na₃AlF₆, Na₅Al₃F₁₄, ZnS, ZnSe, and combinations thereof.

15. The process of claim 11, further comprising forming an epitaxial region which includes a portion of the surface of the substrate body exposed from the patterned structures and a portion of the first portion uncovered by the second portion, the epitaxial region having an area less than 14% of a total area of the surface of the substrate body.

16. A light-emitting diode, comprising:
a patterned substrate according to claim 1; and
a semiconductor epitaxial structure formed on said surface of said substrate body of said patterned substrate that has said patterned structures.

17. The light-emitting diode of claim 16, wherein said semiconductor epitaxial structure comprises a first semiconductor layer, an active layer and a second semiconductor layer arranged in such order, wherein said second semiconductor layer includes a semiconductor material with a different PN type from that of said first semiconductor layer.

18. A process for preparing a light-emitting diode, comprising:
(A) preparing a patterned substrate according to the process of claim 11; and
(B) forming a semiconductor epitaxial structure on a surface of the patterned substrate that has the patterned structures.

19. The process of claim 18, further comprising forming an epitaxial region which includes a portion of the surface of the substrate body exposed from the patterned structures and a portion of the first portion uncovered by the second portion, the epitaxial region having an area less than 14% of a total area of the surface of the substrate body.

20. The process of claim 18, wherein the semiconductor epitaxial structure comprises a first semiconductor layer, an active layer and a second semiconductor layer arranged in such order on the surface of the patterned substrate, wherein the second semiconductor layer includes a semiconductor material of a different PN type from that of the first semiconductor layer.
